(19) United States
(12) Patent Application Publication
(10) Pub. No.: US 2008/0096142 A1
(43) Pub. Date: Apr. 24, 2008

(54) Baking apparatus, substrate heat treatment method and semiconductor device manufacturing method for using baking apparatus, pattern forming method and semiconductor device manufacturing method for using pattern forming method

(76) Inventors: Tsuyoshi Shibata, Kanagawa (JP); Yuuji Kobayashi, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/907,352

(22) Filed: Oct. 11, 2007

Related U.S. Application Data
(62) Division of application No. 10/792,863, filed on Mar. 5, 2004, now abandoned.

(30) Foreign Application Priority Data
Mar. 6, 2003 (JP) 2003-59399
Apr. 17, 2003 (JP) 2003-112928

(51) Int. Cl. G03F 7/40

(52) U.S. Cl. 430/330; 430/30

(57) ABSTRACT

A baking apparatus according to one embodiment of the invention includes a hotplate which performs heat treatment to a substrate placed on the hotplate, a base which has at least three support pins passing through through-holes made in the hotplate and supporting the substrate on the hotplate from a backside of the substrate and is vertically movably placed, and a plurality of sensors which are provided at a tip portion of each support pin respectively and sense contact with the substrate. A pattern forming method according to one embodiment of the invention includes forming an antireflection film and a resist film on a substrate to be processed and forming a resist pattern by performing pattern exposing. onto the resist film, baking, and development process (S01 to S06) measuring a dimension of a predetermined monitor pattern after the formation of the resist pattern (S07), and controlling a heat treatment condition of the resist pattern to deform the resist pattern on the basis of information obtained by measurement of the monitor pattern so that the resist pattern becomes the desired dimension (S08-S13).

### CROSS REFERENCE TO RELATED APPLICATION

The subject application is related to subject matters disclosed in Japanese Patent Applications No. 2003-059399 filed on Mar. 6, 2003 and No. 2003-112928 filed on Apr. 17, 2003 in Japan to which the subject application claims priority under Paris Convention and which are incorporated herein by reference.

### BACKGROUND OF THE INVENTION

1. Field of the Invention

The present invention relates to a baking apparatus which is used for heat treatment of a substrate in a process of manufacturing various kinds of substrates such as a semiconductor substrate for a semiconductor device, a glass substrate for a photomask, and a glass substrate for a liquid crystal display device or the like, and a substrate heat treatment method and a semiconductor device manufacturing method which use the baking apparatus.

The invention also relates to a method which forms a resist pattern having a desired pattern dimension on the substrate to be processed, particularly to the pattern forming method which is preferable to formation of a fine pattern of the semiconductor device and the semiconductor device manufacturing method which uses the pattern.

2. Related Background Art

Particularly, the baking apparatus which performs heat treatment to the semiconductor substrate in a semiconductor device manufacturing process is heavily used in a lithography process.

A drying process after formation of a resist film on the semiconductor substrate by spin coating, a post exposure bake (PEB) process in which a photogenerated acid in the resist film is diffused to homogenize concentration distribution after transferring a pattern to the photoresist film, and the like can be thought as a specific application of the baking apparatus. Further, in recent years, the baking apparatus is also used for a flow bake process in which a pattern dimension is arbitrarily changed by heating the semiconductor substrate to thermally deform the pattern after performing development process to form the pattern.

In addition to the lithography process, the baking apparatus is also used for quenching in which semiconductor substrate temperature is rapidly cooled from the temperature above a melting point of copper to the room temperature in order to homogenize copper distribution in an aluminum copper (Al—Cu) film.

In all the processes, accuracy of temperature control to the semiconductor substrate and uniformity of the temperature in the whole of the semiconductor substrate are very important.

With reference to the temperature accuracy of the baking apparatus, for example, the temperature accuracy of about ±0.2° C. has been already realized in a hotplate included in the baking apparatus which processes the semiconductor substrate having an eight-inch diameter.

However, with reference to the uniformity of the process temperature in the baking apparatus, the apparatus having the sufficiently high accuracy of the uniformity of the process temperature as well as means for confirming whether the semiconductor substrate is processed over the substrate at the uniform process temperature or not have not yet been realized. This problem and measures for accurately placing the semiconductor substrate on a central portion of the hotplate will be described below. FIGS. 1A and 1B are a plan view and a side view showing a state in which the semiconductor substrate is placed in a central portion on a hotplate of the baking apparatus, and FIGS. 2A and 2B are the plan view and the de view showing the state in which the semiconductor substrate is placed on the hotplate of the baking apparatus with the semiconductor substrate offset from the central portion of the hotplate.

As shown in FIGS. 1A and 1B, in the case where the heat treatment is performed while the semiconductor substrate is placed on the central portion without protruding from the hotplate, uniformity of treatment temperature is secured and a problem is not generated in quality of the semiconductor substrate.

However, as shown in FIGS. 2A and 2B, sometimes the semiconductor substrate is placed on the hotplate with a part of the semiconductor substrate protruding from the hotplate.

Such positional shift is caused by coordinate shift of a robot arm which conveys the semiconductor substrate onto the hotplate, and the coordinate shift of the robot arm is caused by lack of adjustment of the robot arm, aging deterioration, or accidental generation of noise.

In the case where a degree of the positional shift is larger, the robot arm and the semiconductor substrate collide with each other at an unexpected position when the robot arm brings out the semiconductor substrate from the baking apparatus, and there is a possibility that one of or both the robot arm and the semiconductor substrate are destroyed.

Therefore, a mechanism preventing the positional shift of the semiconductor substrate is usually provided in the baking apparatus.

FIGS. 3A and 3B are the plan view and the side view of the hotplate of the baking apparatus with the mechanism preventing the positional shift of the semiconductor substrate.

In the baking apparatus shown in FIGS. 3A and 3B, guide members 2 preventing the positional shift of a semiconductor substrate 6 are provided at four points on a periphery of a hotplate 1. The guide member 2 is usually used as the mechanism preventing the positional shift of the semiconductor substrate. For example, like the guide member 2 shown in FIGS. 3A and 3B, the guide member, in which an upper surface of a prism-shaped or cylindrical member is formed in the shape of an inclined surface whose central portion side of the hotplate 1 is lower than the outer peripheral side, is provided in a part or the whole of the periphery of the hotplate 1. As a result, even if an end portion of the semiconductor substrate 6 runs on the guide member 2 by the positional shift, the positional shift of the semiconductor substrate 6 is adjusted in such a manner that the end portion of the semiconductor substrate is slid onto the central portion side of the hotplate 1, and convey trouble caused by the positional shift of the semiconductor substrate is prevented.

However, even if the above guide member 2 is provided in the periphery of the hotplate 1, sometimes there is generated a phenomenon of one-sided run-on, in which the end portion of the semiconductor substrate 6 which runs on the guide member 2 by the positional shift is stopped halfway resulting in that the semiconductor substrate 6 is not slid down to the central portion side of the hotplate 1 completely.

FIG. 4 is the side view of the semiconductor substrate and the hotplate showing the state in which the semiconductor substrate is stopped while one side of the semiconductor substrate runs on the guide member.

As shown in FIG. 4, when the heat treatment is performed to the semiconductor substrate 6 while the semiconductor substrate 6 is still in the state of the one-sided run-on, in a space surrounded by a broken line shown in FIG. 4, a nonuniform gap is generated between the semiconductor substrate 6 and the hotplate 1. As a result, in regions of the semiconductor substrate 6, there is generated difference in heat quantity which is directly and indirectly given to the semiconductor substrate 6 from the hotplate 1, which results in performance of the nonuniform heat treatment over the semiconductor substrate.

When the nonuniform heat treatment is performed to the semiconductor substrate, nonuniformity of a film thickness of a resist occurs in a drying process after resist coating, and defective dimension occurs in the PEB process or a flow bake process.

In the photolithography process, usually a pattern dimension of the semiconductor substrate after pattern formation is measured with a scanning electron microscope (SEM) or the like. In the case where the pattern dimension is out of an allowance, reprocessing is performed.

However, because dimensional variations or dimensional defect caused by the positional shift of the semiconductor substrate is the completely irregular phenomenon, even if dimensional measurement sampling is performed at several points per each semiconductor substrate without failure, it is very difficult to find which part of the semiconductor substrate generates dimensional variations or dimensional defect or which semiconductor substrate generates the dimensional variations or the dimensional defect.

Therefore, for the purpose of the means for sensing the one-sided run-on of the semiconductor substrate on the hotplate, a sensing mechanism which utilizes the temperature characteristics of the hotplate is provided in the conventional baking apparatus.

In the sensing mechanism, the temperature characteristics of the hotplate in normally placing the semiconductor substrate of a sensing subject on the hotplate to come into contact with the hotplate is used as a comparative model. When the semiconductor substrate of the sensing subject is placed on the hotplate, by measuring the temperature characteristics of the hotplate to compare to the comparative model, whether the difference in the temperature characteristics is in the range of an allowance or not is recognized to sense the on-sided run-on.

FIG. 5 is a graph showing temperature characteristics of the hot plate measured by a mechanism sensing the one-sided run-on of the semiconductor substrate. A curve 1 among the curves shown in the graph of FIG. 5 is the temperature characteristics of the hotplate when the semiconductor substrate is normally placed on the hotplate whose temperature is set to 160° C. to come into contact with the hot plate, and a curve 2 is the temperature characteristics of the hotplate when the semiconductor substrate is placed on the hotplate whose temperature is set to 160° C. while the semiconductor substrate is in the state of one-sided run-on.

When the semiconductor substrate having the relatively low temperature is placed on the hotplate heated to the higher temperature, the hotplate temperature is temporarily decreased due to the temperature difference between the semiconductor substrate and the hotplate. At this point, assuming that a decrease in the temperature in normally placing the semiconductor substrate on the hotplate to come into contact with the hotplate is set to ΔT, the decrease in the temperature becomes ΔT′ (<ΔT) when a part of the semiconductor substrate is in contact with the hotplate with the semiconductor substrate placed in the state of the one-sided run-on. As shown in FIG. 5, it is found that the decrease in the temperature in the case where a part of the semiconductor substrate is in contact with the hotplate while the semiconductor substrate is placed in the state of the one-sided run-on ΔT′ is smaller than the decrease in the temperature in normally placing the semiconductor substrate on the hotplate to come into contact with the hotplate ΔT.

Therefore, in the sensing mechanism, an allowable threshold is previously set to the decrease in the temperature ΔT, and the temperature characteristics of the hotplate is actually measured when the semiconductor substrate is placed on the hotplate. When the amount of decrease in the temperature is larger than the allowable threshold, it is decided that the semiconductor substrate has been normally placed on the hotplate and the normal heat treatment has been performed. When the amount of decrease in the temperature is smaller than the allowable threshold, it is decided that the semiconductor substrate has not been normally placed on the hotplate by the one-sided run-on and the heat treatment has been performed at the nonuniform temperature.

The method and the apparatus, which decide whether the semiconductor substrate is normally placed on the hotplate or not by utilizing the temperature characteristics of the hotplate in placing the semiconductor substrate on the hotplate, have been already proposed. For example, see Japanese Patent Laid-Open Publication No. 2002-050557 and Japanese Patent Laid-Open Publication No. 2000-306825.

The method and the apparatus, which directly senses the temperature of the semiconductor substrate by providing a thermocouple inside a support pin for supporting the semiconductor substrate in moving the semiconductor substrate onto the hotplate or from the hotplate, have been also proposed. For example, see Japanese Patent Laid-Open Publication No. H11(0411)-272342 (1999).

However, in the setting of the allowable threshold of the amount of decrease in the temperature ΔT, the fine adjustment is very strictly required. When the allowable threshold is too small, failure treatment is missed when the one-sided run-on of the semiconductor substrate is generated. On the other hand, when the allowable threshold is too large, the sensing of failure treatment is performed when the normal heat treatment is performed. Accordingly, in the method of setting of the allowable threshold, currently the sufficient accuracy is not always obtained for the actual failure sensing.

Further, the temperature characteristics of the hotplate in normally placing the semiconductor substrate on the hotplate to come into contact with the hotplate, namely the amount of decrease in the temperature ΔT depends on the temperature setting of the hotplate.

FIG. 6 is the graph showing an amount of decrease in temperature ΔT of the hotplate in each setting temperature of the hotplate when the semiconductor substrate is normally placed on the hotplate to come into contact with the hotplate.

As shown in FIG. 6, when the semiconductor substrate is normally placed on the hotplate to come into contact with the hotplate, it is found that the amount of decrease in temperature ΔT of the hotplate in each setting temperature of the hotplate becomes larger as the setting temperature of the hotplate is increased.

However, in order that one hotplate is changed to the plurality of temperature settings while the setting of the allowable threshold of the amount of decrease in temperature ΔT is changed, since very troublesome and difficult operation is required, the plurality of baking apparatuses should be prepared for each setting temperature, and cost of facility is increased in the end.

By the way, as packing density of the semiconductor device is increased, the finer pattern is required more and more.

In order to correspond to the finer pattern, progress in an exposure apparatus and a mask making technique is remarkable, and high-performance exposure apparatus such as a shorter wavelength of a light source and high NA of a lens and ultra-fine resolution technology such as a phase shift method and an oblique incident exposure can be thought as an example of such progress.

The method, in which the resist pattern is deformed by performing the heat treatment to the resist pattern and obtains the finer pattern, is known as one of the methods of forming the fine pattern such that the fine pattern can not be formed by adopting the above technologies.

As shown in FIG. 7A, the heat treatment is performed to a resist pattern 102 having an aperture width Wa, which is formed on a substrate to be processed 101, and reflow of the resist pattern is performed to widen the resist pattern 102 in a horizontal direction. Then, a finer aperture width Wb is obtained as shown in FIG. 7B.

However, in this resist pattern forming method, in the case where a process condition is changed during the operation of the apparatus, the desired-pattern dimension can not be obtained. For example, in the case where the heat treatment is not sufficient, the resist pattern 102 having a large aperture width Wc is formed as shown in FIG. 7C. In the case where the heat treatment is excessive, the resist pattern 102 having the collapsed pattern as shown in FIG. 7D.

The pattern forming method, in which feedback is performed so that the heat treatment is finished at the time when the aperture width becomes the desired value by measuring an amount of deformation of the resist, is known in order to solve the problem. For example, see Japanese Patent Laid-Open Publication No. 2002-06404.7 (particularly page 3 and FIG. 1) and Japanese Patent Laid-Open Publication No. 2000-091203 (particularly page 3 and FIG. 1).

The pattern forming method disclosed in Japanese Patent Laid-Open Publication No. 2002-064047 will be described referring to FIG. 8. As shown in FIG. 8, both the resist pattern 102 and a monitor pattern 103 are formed on the substrate to be processed 101, and the film thickness or an optical constant of the monitor pattern 103 is sensed with a spectral ellipsometer 104.

When the resist 102 is started to reflow by the heat treatment, the amount of deformation of the resist is indirectly measured from the amount of change in the film thickness or the optical constant of the monitor pattern 103, and the heat treatment is finished at the time when the amount of deformation of the resist reaches the desired amount of deformation.

In the pattern forming method disclosed in Japanese Patent Laid-Open Publication No. 2000-091203, the amount of deformation of the resist is indirectly measured from the change in amplitude of a sensed signal corresponding to a diffraction light beam obtained by irradiating the monitor pattern with a laser beam, and the heat treatment is finished at the time when the amount of deformation of the resist reaches the desired amount of deformation.

However, in the method disclosed in Japanese Patent Laid-Open Publication No. 2002-064047 or Japanese Patent Laid-Open Publication No. 2000-091203, although the desired resist pattern dimension is obtained in the vicinity of the monitor pattern, the desired resist pattern dimension is not obtained in the place besides the vicinity of the monitor pattern, so that there is the problem that the method can not correspond to variations in an in-plane distribution of the substrate to be processed.

The variation in dimension of the resist pattern are already present in advance of the heat treatment in the plane of the substrate to be processed and among the substrates to be processed, because fluctuation factors of the process are present in each of the processes of resist coating, exposure, baking, and development which are of the usually lithography process.

The variations in dimension can not be improved by the method of feedback disclosed in Japanese Patent Laid-Open Publication No. 2002-064047 or Japanese Patent Laid-Open Publication No. 2000-091203.

Since the amount of deformation of the resist is not always stabilized in the plane of the substrate to be processed due to the nonuniformity of the temperature distribution of the heat treatment apparatus, the desired pattern dimension is not finally obtained, and not ignorable amount of defectives are generated. As a result, in order to recover the substrate to be processed which has become the defective of the pattern dimension, there is generated the problem that a rework ratio is increase in the lithography process.

Further, in order to indirectly measure the amount of deformation of the resist pattern in real time during the heat treatment, there is also generated the problem that the huge and complicated apparatus including a precise measuring device with a laser device or a controller for the feedback is required.

Therefore, in the pattern forming methods disclosed in Japanese Patent Laid-Open Publication No. 2002-064047 and Japanese Patent Laid-Open Publication No. 2000-091203, the fluctuation factors, such as the variations in resist pattern dimension before the heat treatment in the plane of the substrate to be processed or among the substrates to be processed and the variation in amount of deformation of the resist caused by the nonuniformity of the temperature distribution of the heat treatment apparatus, can not be suppressed and the resist pattern having the desired dimension can not be obtained, so that there is the problem that the pattern forming methods disclosed in Japanese Patent Laid-Open Publication No. 2002-064047 and Japanese Patent Laid-Open Publication No. 2000-091203 can not take up the variations in in-plane distribution of the substrate to be processed.

### SUMMARY OF THE INVENTION

According to one embodiment of the present invention, there is provided with a baking apparatus comprising:

a hotplate which performs heat treatment to a substrate placed on the hotplate;

a base which has at least three support pins passing through through-holes made in the hotplate and supporting the substrate on the hotplate from a backside of the substrate, the base being vertically movably placed; and

a plurality of sensors which are provided at a tip portion of the each support pin respectively, the plurality of sensors sensing contact with the substrate.

According to one embodiment of the present invention, there is provided with a substrate heat treatment method including performance of heat treatment to a substrate by using a baking apparatus comprising:

a hotplate which performs heat treatment to a substrate placed on the hotplate;

a base which has at least three support pins passing through through-holes made in the hotplate and supporting the substrate on the hotplate from a backside of the substrate, the base being vertically movably placed; and

a plurality of sensors which are provided at a tip portion of the each support pin respectively, the plurality of sensors sensing contact with the substrate.

According to one embodiment of the present invention, there is provided with a semiconductor device manufacturing method including performance of heat treatment to a substrate by using a baking apparatus comprising:

a hotplate which performs heat treatment to a substrate placed on the hotplate;

a base which has at least three support pins passing through through-holes made in the hotplate and supporting the substrate on the hotplate from a backside of the substrate, the base being vertically movably placed; and

a plurality of sensors which are provided at a tip portion of the each support pin respectively, the plurality of sensors sensing contact with the substrate.

According to one embodiment of the present invention, there is provided with a pattern forming method comprising:

forming a resist film on a substrate to be processed, and forming a resist pattern including a monitor pattern by exposing a pattern onto the resist film to perform baking and development process;

measuring a dimension of the monitor pattern arranged in the resist pattern, and determining an average value of the monitor pattern dimension in a plane of the substrate to be processed; and

comparing the average value and a predetermined reference value, and controlling a heat treatment condition to deform the resist pattern so that the resist pattern becomes the desired dimension.

According to another embodiment of the present invention, there is provided with a pattern forming method comprising:

forming a resist film on a substrate to be processed, and forming a resist pattern including a monitor pattern by exposing a pattern onto the resist film to perform baking and development process;

measuring a dimension of the monitor pattern arranged in the resist pattern, and determining a pattern dimension distribution in a plane of the substrate to be processed; and

comparing the distribution in the plane of the substrate and a predetermined reference value, and controlling a heat treatment condition to deform the resist pattern so that the resist pattern becomes the desired dimension.

According to another embodiment of the present invention, there is provided with a semiconductor device manufacturing method which processes a substrate to be processed by using a resist pattern to form a semiconductor device after heat treatment of the resist pattern formed on the substrate to be processed is performed to obtain the resist pattern having a desired pattern dimension,

the semiconductor device manufacturing method forming the resist pattern having the desired pattern dimension comprising:

forming a resist film on the substrate to be processed, and forming a resist pattern including a monitor pattern by exposing a pattern onto the resist film to perform baking and development process;

measuring a dimension of the monitor pattern arranged in the resist pattern, and determining an average value of the monitor pattern dimension in a plane of the substrate to be processed; and

comparing the average value and a predetermined reference value, and controlling a heat treatment condition to deform the resist pattern so that the resist pattern becomes the desired dimension.

According to another embodiment of the present invention, there is provided with a semiconductor device manufacturing method which processes a substrate to be processed by using a resist pattern to form a semiconductor device after heat treatment of the resist pattern formed on the substrate to be processed is performed to obtain the resist pattern having a desired pattern dimension,

the semiconductor device manufacturing method forming the semiconductor device by processing the substrate to be processed with the resist pattern comprising:

forming a resist film on the substrate to be processed, and forming a resist pattern including a monitor pattern by exposing a pattern onto the resist film to perform baking and development process;

measuring a dimension of the monitor pattern arranged in the resist pattern, and determining an distribution of the pattern dimension of the substrate to be processed; and

comparing the in-plane distribution and a predetermined reference value, and controlling a heat treatment condition to deform the resist pattern so that the resist pattern becomes the desired dimension.

### BRIEF DESCRIPTION OF THE DRAWINGS

FIGS. 1A and 1B are a plan view and a side view showing a state in which a semiconductors substrate is placed in a central portion on a hotplate of a baking apparatus

FIGS. 2A and 2B are a plan view and a side view showing a state in which the semiconductor substrate is placed on the hotplate of the baking apparatus with the semiconductor substrate offset from the central portion of the hotplate;

FIGS. 3A and 3B are a plan view and a side view of the hotplate of the baking apparatus with a mechanism preventing positional shift of the semiconductor substrate;

FIG. 4 is a side view of the semiconductor substrate and the hotplate showing a state in which the semiconductor substrate is stopped while one side of the semiconductor substrate runs on a guide member;

FIG. 5 is a graph showing temperature characteristics of the hotplate measured by a mechanism sensing the one-sided run-on of the semiconductor substrate;

FIG. 6 is a graph showing an amount of decrease in temperature ΔT of the hotplate in each setting temperature of the hotplate when the semiconductor substrate is normally placed on the hotplate to come into contact with the hotplate;

FIGS. 7A to 7D are a schematic sectional view showing the conventional resist pattern forming method;

FIG. 8 is a schematic sectional view showing the conventional pattern forming method in which a deformation amount of a resist is measured to feed back to heat treatment time;

FIGS. 9A and 9B are a plan view and a side view showing the hotplate and its periphery of the baking apparatus according to a first embodiment of the invention;

FIG. 10 is a side view showing one process in a series of operations of the baking apparatus according to the first embodiment of the invention;

FIG. 11 is a side view showing one process in a series of operations of the baking apparatus according to the first embodiment of the invention;

FIG. 12 is a side view showing one process in a series of operations of the baking apparatus according to the first embodiment of the invention;

FIG. 13 is a side view showing one process in a series of operations of the baking apparatus according to the first embodiment of the invention;

FIG. 14 is a side view showing one process in a series of operations of the baking apparatus according to the first embodiment of the invention;

FIG. 15 is a side view showing a state in which the one-sided run-on of the semiconductor substrate is generated in the baking apparatus according to the first embodiment of the invention;

FIG. 16 is a flow chart-showing the pattern forming method according to a second embodiment of the invention;

FIGS. 17A and 17B are a view showing a relationship between a heat treatment condition and a resist pattern dimension in the second embodiment of the invention, in particular, FIG. 17A shows the relationship between heating temperature and the resist pattern dimension, and FIG. 17B shows the relationship between heating time and the resist pattern dimension;

FIG. 18 shows a distribution of the resist pattern dimension in the substrates in the second embodiment of the invention;

FIG. 19 is a flow chart showing the pattern forming method according to a third embodiment of the invention;

FIGS. 20A and 20B show the hotplate according to the third embodiment of the invention, FIG. 20A is a plan view showing a heater array, and FIG. 20B is a sectional view taken on line A-A of FIG. 20A and viewed in a narrow direction;

FIGS. 21A and 21B show a heat treatment process in which the resist is deformed with the hotplate according to the third embodiment of the invention, in particular, FIG. 21A shows an in-plane distribution of a monitor pattern dimension on the substrate after development, and FIG. 21B shows a temperature distribution of the hotplate;

FIG. 22 shows the in-plane distribution of the resist pattern dimension on the substrate in the third embodiment of the invention;

FIGS. 23A to 23C show the hotplate according to modifications of the third embodiment of the invention, in particular, FIG. 23A is a plan view showing an arcuate heater array, FIG. 23B is a plan view showing the arcuate heater array and an annular heater array, and FIG. 23C is a plan view showing the annular heater array; and

FIG. 24 shows a flow chart of a semiconductor device manufacturing method which adopts the pattern forming method according to a fourth embodiment of the invention.

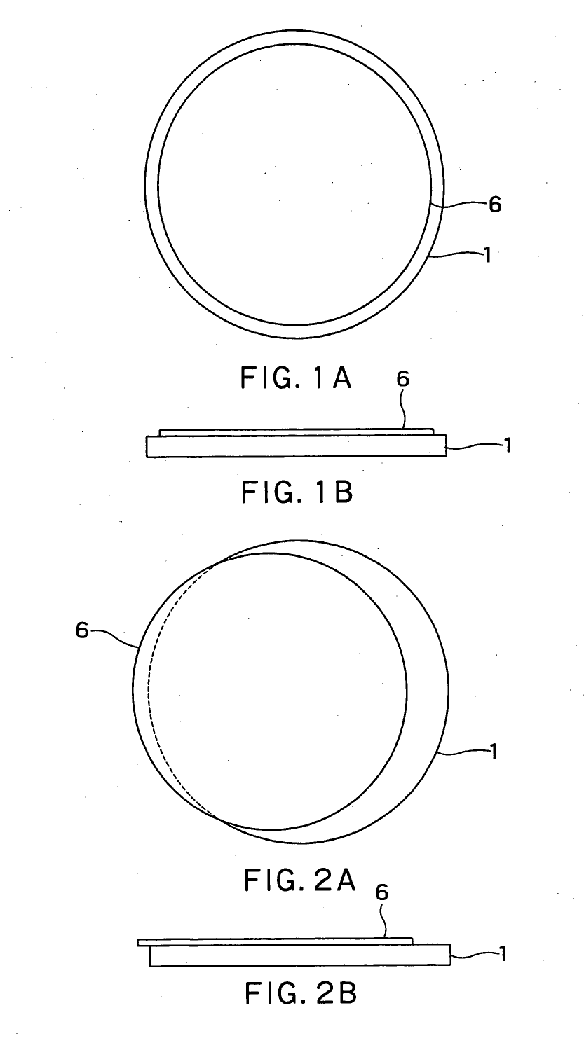

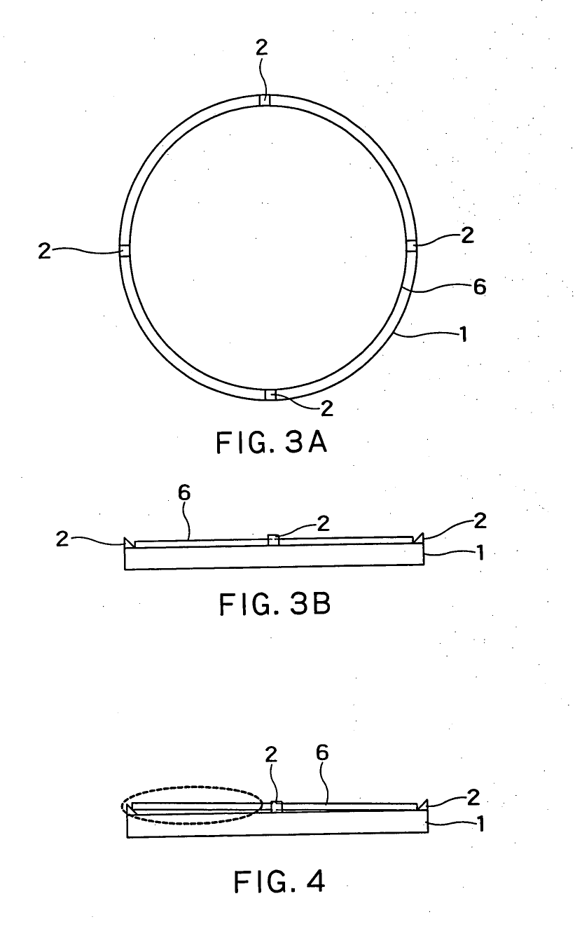

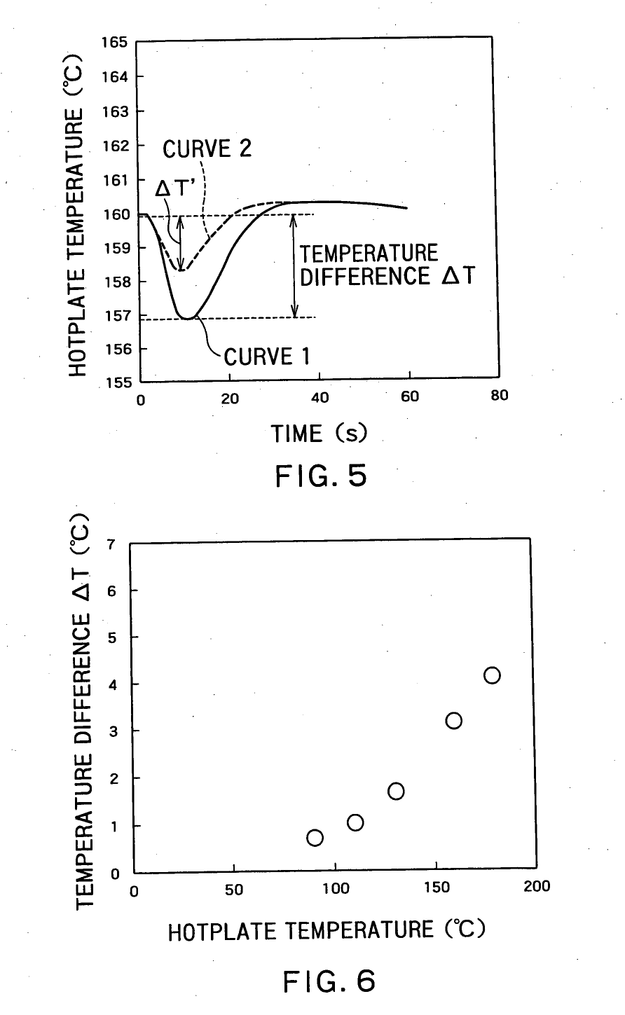

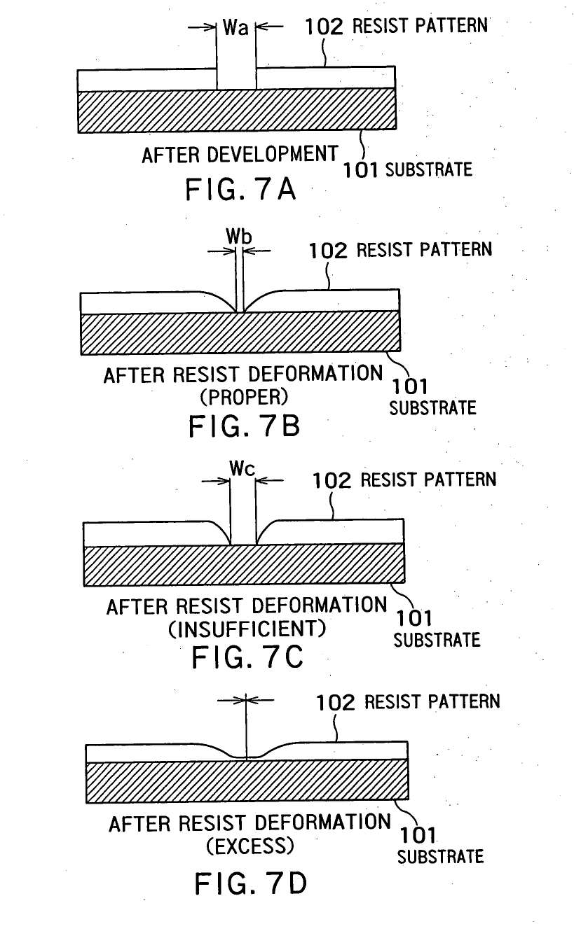

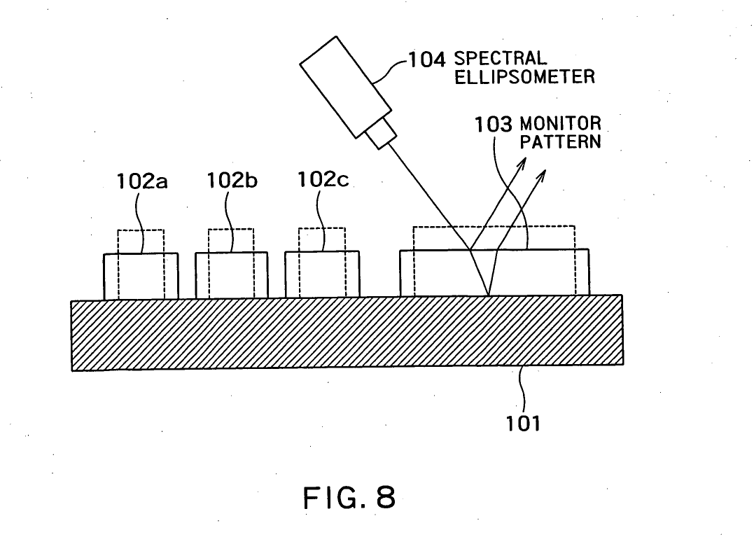

### DETAILED DESCRIPTION OF THE INVENTION

The baking apparatus according to a first embodiment of the invention will be described below referring to the accompanying drawings.

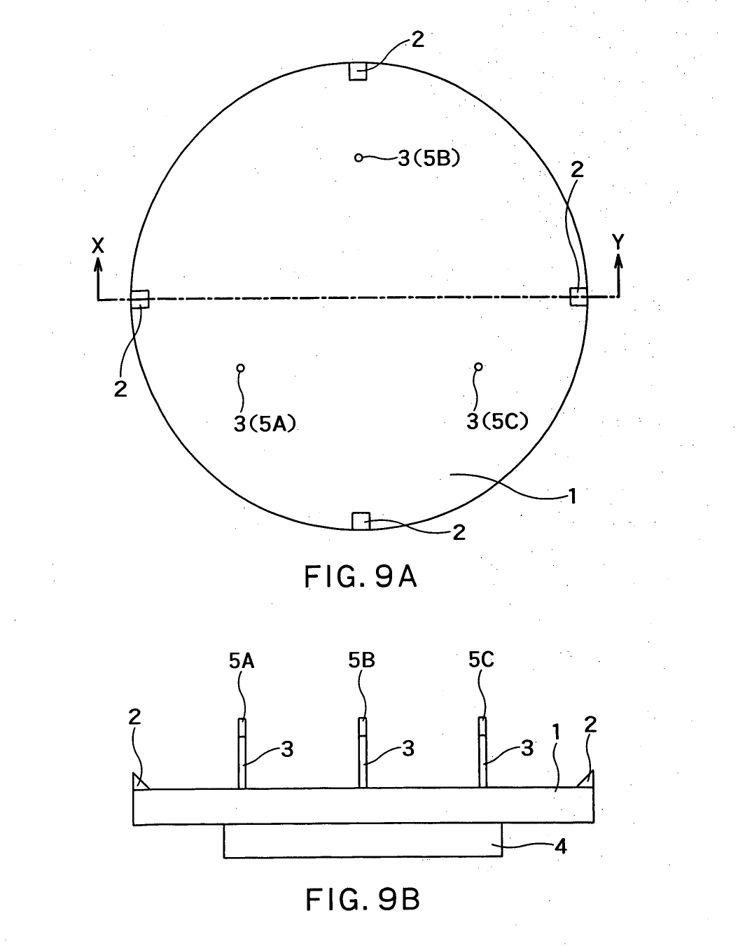

FIGS. 9A and 9B are a plan view and a side view showing the hotplate and its periphery of the baking apparatus according to the first embodiment of the invention.

The baking apparatus according to the first embodiment of the invention includes a hotplate 1 which performs heat treatment to the semiconductor substrate placed on the hotplate, a base 4 which has at least three support pins 3 passing through through-holes made in the hotplate 1 and supporting the semiconductor substrate on the hotplate 1 from a backside of the semiconductor substrate, and which is vertically movably placed, a guide member 2 which is provided in a part or the whole of the periphery of the hotplate 1, and which has an upper surface formed in the shape of an inclined surface whose central portion side of the hotplate 1 is lower than the outer peripheral side of the hotplate 1, and a plurality of sensors 5A, 5B, and 5C which are respectively provided at tip portions of each support pin 3 and sense contact with the semiconductor substrate.

A diameter of the hotplate 1 is, for example, 210 mm. In this case, the specific shape of the guide member 2 is a prism-shaped member. The upper surface of the prism-shaped member is formed in the shape of the inclined surface whose central portion side of the hotplate 1 is lower than the outer peripheral side of the hotplate 1, and the guide members 2 are provided at four places in the periphery of the hotplate 1 respectively. It is also possible that the upper surface of a cylindrical member having the diameter of 2 mm and a height of 3 mm which is formed in the shape of the inclined surface whose central portion side of the hotplate 1 is lower than the outer peripheral side of the hotplate 1 is used as the guide member 2 and the cylindrical members are respectively provided at four places in the periphery whose distance from the center of the hotplate 1 is, e.g. 102 mm. The specific shape and the setting place of the guide member 2 are arbitrary in the periphery of the hotplate 1.

At least three support pins 3 can be provided in the base 4 respectively so that a horizontal single plane is formed by the tips of the support pins 3 and the semiconductor substrate is supported from the backside of the semiconductor substrate by them. In this case, the three support pins 3 are arranged in the shape of an equilateral triangle having a side of 150 mm. It is also possible to use four or more support pins 3.

The base 4 includes a mechanism which vertically moves the base 4. The semiconductor substrate supported from the backside by the support pins 3 can be vertically moved on the hotplate 1 by moving the base 4 vertically. The mechanism which vertically moves the base 4 can operate when the semiconductor substrate is moved between a robot arm and the baking apparatus.

In the baking apparatus according to the first embodiment of the invention, the sensors 5A, 5B, and 5C which sense the contact with the semiconductor substrate 6 are provided at the tip portions of each supports pin 3 respectively. Each of the sensors 5A, 5B, and 5C independently senses the contact with the semiconductor substrate 6. Any sensor having a function of sensing the contact with the semiconductor substrate can be used as the sensor 5. In this case, a piezoelectric element utilizing PZT (lead zirconate titanate) is used. It is also possible that a capacitance type element is used as the sensor 5.

The operation and the function will be described on the basis of a configuration of the baking apparatus according to the first embodiment of the invention described above.

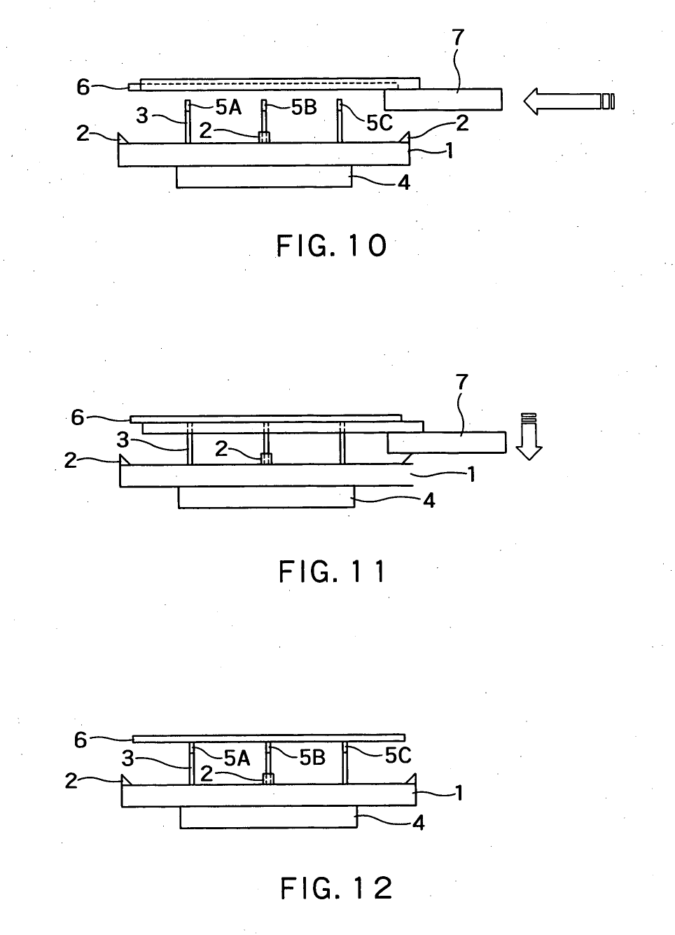

FIGS. 10 to 14 are the side views showing a series of operations of the baking apparatus according to the first embodiment of the invention. FIG. 15 is the side view showing a state in which one-sided run-on of the semiconductor substrate is generated in the baking apparatus according to the first embodiment of the invention.

As shown in FIG. 10, a semiconductor substrate 6 which is a subject of heat treatment is conveyed into a space on the hotplate 1 within the baking apparatus by a robot arm 7. At this point, the base 4 is adjusted so that the tips of the support pins 3 are projected from the upper surface of the hotplate 1 and supports pins do not come into contact with the semiconductor substrate 6 on the robot arm 7.

Then, as shown in FIG. 11, the robot arm 7 is moved downward so that the semiconductor substrate 6 is supported by the support pins 3. After the semiconductor substrate 6 is placed on the support pins 3, the robot arm 7 is moved out of the baking apparatus as shown in FIG. 12.

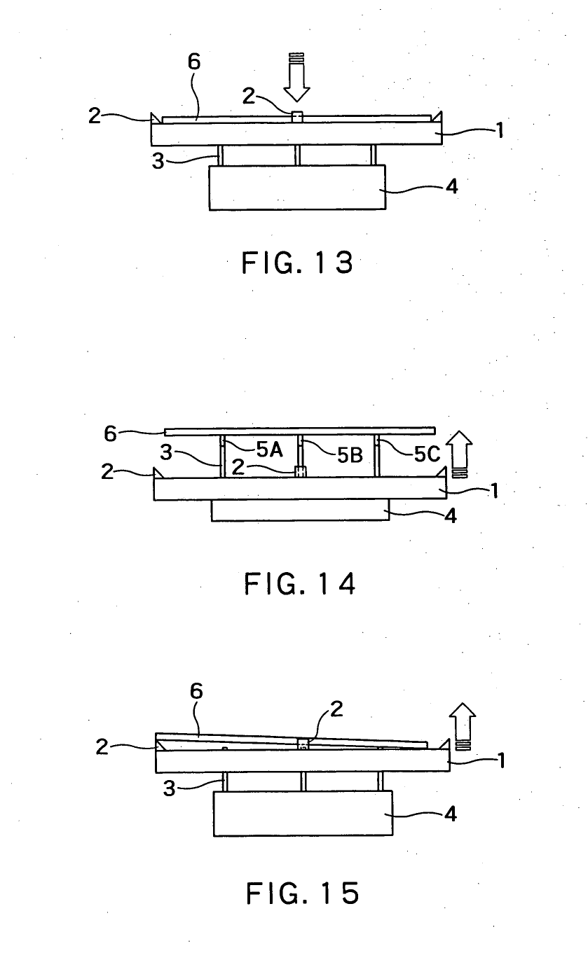

After the robot arm is moved out of the baking apparatus, in order to place the semiconductor substrate 6 onto the hotplate 1 to perform the heat treatment, as shown in FIG. 13, the base 4 is moved downward, the semiconductor substrate 6 is placed on the hotplate 1 while the tips of the support pins 3 is set at a level lower than the upper surface of the hotplate 1, and the heat treatment is performed to the semiconductor substrate 6.

As shown in FIG. 14, after the heat treatment is finished, the tips of the support pins 3 are caused to project from the upper surface of the hotplate 1 by moving the base 4 upward, and the semiconductor substrate 6 is lifted from the upper surface of the hotplate 1 while supported by the support pins 3. At this point, when each of the sensors 5A, 5B, and 5C which are respectively provided at the tip portions of the three support pins 3 senses the contact with the semiconductor substrate 6 at the same time, it is found that the semiconductor substrate 6 has been normally placed on the hotplate 1, and it can be decided that the heat treatment has been normally performed over the whole surface of the semiconductor substrate 6 with uniform temperature.

On the other hand, when the one-sided run-on is generated in such a manner that the peripheral portion of the semiconductor substrate 6 runs on the guide member 2 as shown in FIG. 15, each of the sensors 5A, 5B, and 5C senses the contact with the semiconductor substrate 6 at different timing. For example, as shown in FIG. 15, when the one-sided run-on is generated in the semiconductor substrate 6 to cause an angle between the semiconductor substrate 6 and the hotplate 1 to become 1° as shown in FIG. 15 and it is assumed that the lifting speed of the base 4 is 5 mm/s, at first the sensor 5C comes into contact with the semiconductor substrate 6, the sensor B comes into contact with the semiconductor substrate 6 after 0.26 second from the contact between sensor 5C and the semiconductor substrate 6, and then the sensor 5A comes into contact with the semiconductor substrate 6 after 0.26 second from the contact between sensor 5B and the semiconductor substrate 6.

Accordingly, whether the semiconductor substrate 6 is normally placed on the hotplate 6 or the one-sided run-on of the semiconductor substrate 6 is generated can be sensed by monitoring the contact timing between the semiconductor substrate 6 and each of the sensors 5A, 5B, and 5C.

Specifically, an arbitrary allowance is previously set to time difference in the contact timing between the semiconductor substrate 6 and each of the sensors 5A, 5B, and 5C. When the time difference actually measured is not more than the allowance, it can be decided that the semiconductor substrate 6 is normally placed on the hotplate 1. When the measured time difference exceeds the allowance, it can be decided that the treatment is failed. When the failure treatment is sensed, it is possible that a warning device issues a visual or audio warning, or it is possible that the operation of the baking apparatus is interrupted. Further, when the failure treatment is sensed, it is also possible that the semiconductor substrate which is of a subject of the processing is automatically rejected from a manufacturing process.

In the base 4, when the lifting speed and the lowering speed can be adjusted or at least the lifting speed can be adjusted, detection sensitivity can be adjusted by increasing and decreasing the lifting speed of the base 4.

Similarly, if the time difference in the contact timing caused by the distortion of the semiconductor substrate 6 by itself, inclination of the base 4, and deviation in the heights of the support pins 3 is measured by monitoring the contact timing between the semiconductor substrate 6 and each of the sensors 5A, 5B, and 5C when the semiconductor substrate 6 is moved from the robot arm 7 and placed onto the support pins 3 before the heat treatment as shown in FIG. 11, and the time difference is used as a correction value for the time difference which is measured after the heat treatment, the generation of the one-sided run-on of the semiconductor substrate 6 can be sensed with higher precision.

Although it has been described that the baking apparatus according to the first embodiment of the invention is used for the heat treatment of the substrate in the process of manufacturing the semiconductor substrate for the semiconductor device, the baking apparatus according to the first embodiment of the invention can be also used for the heat treatment of the substrate in the processes of manufacturing various kinds of substrates such as a glass substrate for photo mask and a glass substrate for liquid crystal display device or the like.

In the baking apparatus according to the first embodiment of the invention, it has been described that the guide member 2 is provided in a part of or the whole of the periphery of the hot plate 1. However, the configuration of the invention can be also applied to the case in which the guide member 2 is not provided.

As can be seen from the above description, the invention also relates to the method of performing the heat treatment of the substrate and the method of manufacturing the semiconductor substrate, which include the performance of the heat treatment to the substrate by the use of the baking apparatus according to the first embodiment of the invention.

As described above, the baking apparatus according to the first embodiment of the invention can sense the one-sided run-on of the substrate on the hotplate and the resultant failure of the heat treatment with high precision and low cost, and the generation of the defective piece can be suppressed at the minimum.

Next an embodiment of the pattern forming method of the invention will be described referring to the drawings.

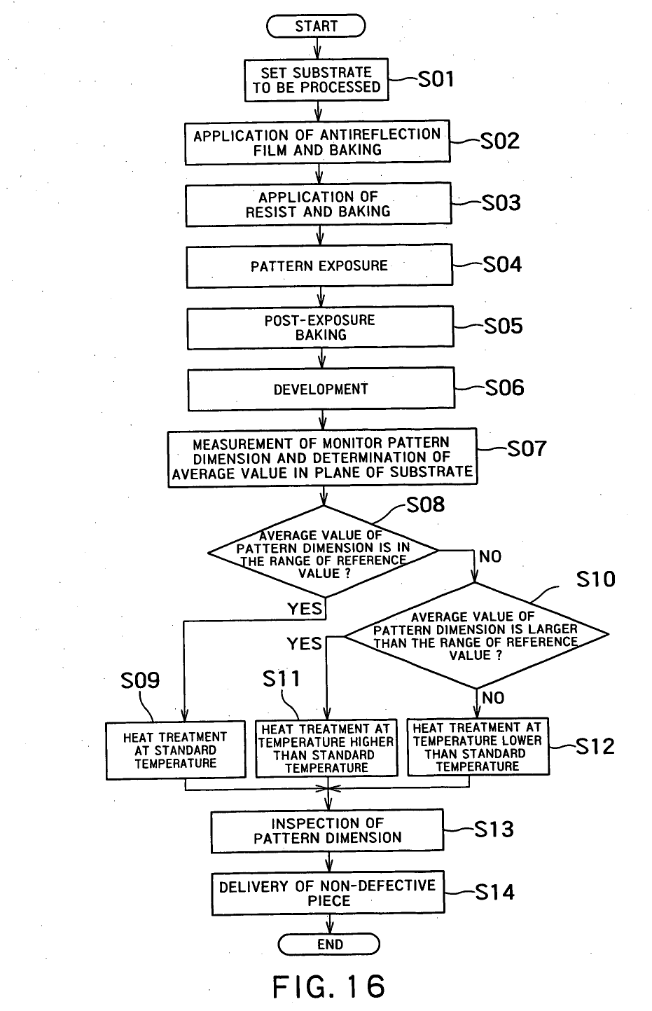

FIG. 16 shows a flow chart of the pattern forming method according to a second embodiment of the invention.

As shown in FIG. 16, twenty substrates to be processed, e.g. 20 silicon substrates (hereinafter simply referred to as substrate) are prepared (First Step S01). In the substrate, a silicon oxide film having a film thickness of 1 μm is formed on the upper surface of the substrate to be processed, and the photolithography will be performed to the silicon oxide film.

An antireflection film made of an organic polymer is coated on the silicon oxide film so that the film thickness becomes 60 nm, and then baking treatment is performed at 190° C. for 60 seconds (Second Step S02).

A KrF positive type chemically amplified resist film is coated on the antireflection film so that the film thickness becomes 480 nm, and then the baking treatment is performed at 110° C. for 60 seconds (Third Step S03).

The resist film is exposed at exposure of 17 mJ/cm² by using a KrF excimer laser scanner under the conditions of NA=0.68, a=0.75, 2/3 orbicular zone illumination, and a half tone mask of transmittance of 6% (Fourth Step S04). The post exposure baking treatment is performed at 130° C. for 60 seconds (Fifth Step S05).

Then, a resist pattern including a contact hole pattern for device having the diameter of 160 nm and various monitor patterns for measurement is formed by development process for 30 seconds with, e.g. a 2.38 wt % tetramethyl ammonium hydroxide (TMAH) aqueous solution (Sixth Step S06).

The monitor patterns, e.g. the contact hole dimensions are measured for all the 20 substrates with SEM (Scanning Electron Microscopy). For example, the contact hole dimension is measured at 10 points per one substrate to determine an average value of the measured points (Seventh Step S07).

It is decided whether the average value is in a range of a reference value determined from a process margin of a photolithography process or not, e.g. the average value is within 160±5 nm or not (Eighth Step S08), the baking temperature is set in each substrate on the basis of the decision result so that the contact hole dimension after the pattern deformation caused by the heat treatment approaches the desired dimension, e.g. 120 nm as much as possible.

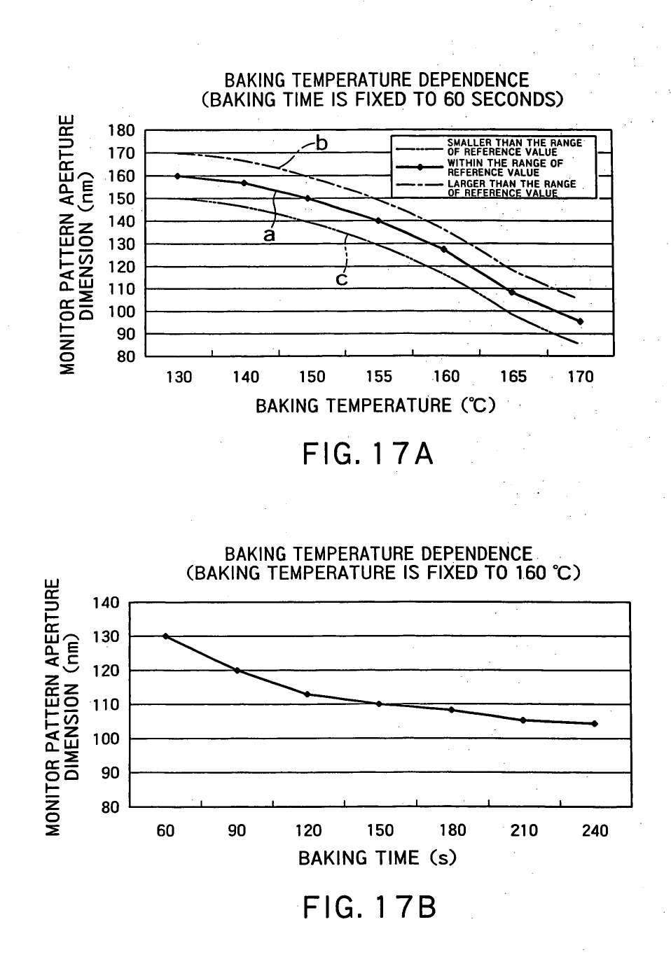

FIGS. 17A and 17B show a relationship between the heat treatment condition and the resist pattern dimension, FIG. 17A shows the relationship between heating temperature and the contact hole dimension, and FIG. 17B shows the relationship between baking time and the contact hole dimension.

Further, in FIG. 17A, a solid line a shows the relationship between the baking temperature and the contact hole dimension when the contact hole dimension after the development is the reference value, e.g. the aperture dimension is 160 nm, an alternate long and short dashed line b shows the relationship between the baking temperature and the contact hole dimension when the contact hole dimension after the development is larger than the reference value, e.g. the aperture dimension is 170 nm, a chain double-dashed line c shows the relationship between the baking temperature and the contact hole dimension when the contact hole dimension after the development is smaller than the reference value, e.g. the aperture dimension is 150 nm.

As can be seen from FIGS. 17A and 17B, experiment shows that the contact hole dimension becomes smaller as the baking temperature is increased and the curve of the aperture dimension to the baking temperature is shifted in substantially parallel depending on the contact hole dimension after the development. As the baking time becomes longer, the contact hole dimension tends to become constant.

Therefore, assuming that the baking time is constant, a thermal flow rate (analytical curve: a rate of a change in dimension per unit temperature) can be determined from the relationship between the baking temperature and the contact hole dimension to set the proper baking temperature. The thermal flow rate of −2.7 nm/° C. was obtained from the experiment.

In the case where the contact hole dimension after the development is in the range of the reference value, e.g. the aperture dimension is 160±5 nm, the heating treatment is performed at a standard temperature which is initially set by the solid line a, e.g. 162° C. (Ninth Step S09).

On the other hand, in the case where the contact hole dimension after the development deviates from the range of the reference value, it is decided whether the contact hole dimension is larger or smaller than the range of the reference value (Tenth Step S10). In the case where the contact hole dimension is larger than the range of the reference value, e.g. the aperture dimension is 170 nm, the heat treatment is performed at the temperature higher than the standard temperature, e.g. 165° C., on the basis of the correlation shown by the alternate long and short dashed line b (Eleventh Step S11). On the contrary, in the case where the contact hole dimension is smaller than the range of the reference value, e.g. the aperture dimension is 150 nm, the heat treatment is performed at the temperature lower than the standard temperature, e.g. 159° C., on the basis of the correlation shown by the chain double-dashed line c (Twelfth Step S12). Therefore, a deformation amount of the resist can be adjusted in each substrate.

The change in baking temperature can be easily performed in such a manner that the plurality of hotplates which are set to the different temperatures are previously prepared and the hotplate which is set to the appropriate temperature is timely selected among the plurality of hotplates.

A post-process inspection of the pattern dimension is performed by using SEM (Thirteenth Step S13), and a non-defective piece is delivered to the next process (Fourteenth Step S14).

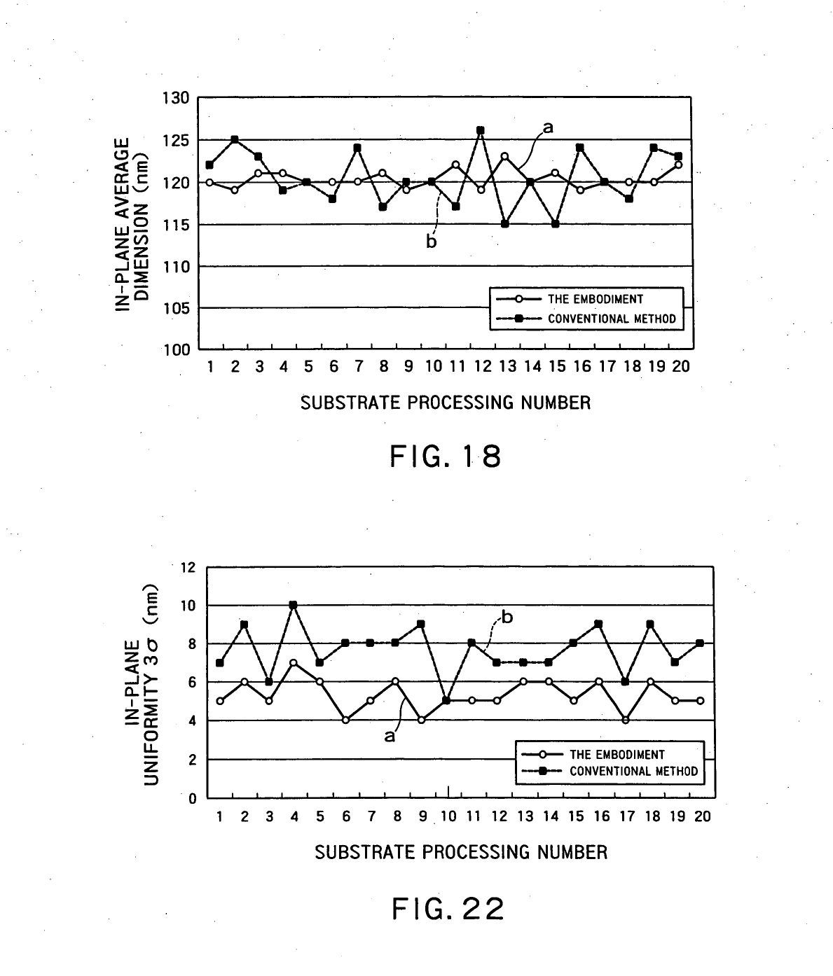

FIG. 18 shows the measurement result of the contact hole pattern dimension after the heat treatment for all the substrates while the measurement result is compared with the conventional method. In FIG. 18, a solid line a shows the result performed by the embodiment of the present invention, and a broken line b shows the result performed by the conventional method. As can be seen from FIG. 18, the experiment shows that substrate variations in average dimension are decreased to one-third compared with the conventional method.

As described above, in the pattern forming method according to the second embodiment, the deformation amount of the resist is controlled in each substrate by the adjustment of the baking temperature by adopting a feed forward method so that the variations in resist pattern dimension after the development are cancelled in the resist pattern deformation process.

Therefore, dimensional accuracy of the resist pattern can be improved, and the desired pattern in which the variations in resist pattern dimension among the substrates fare small can be obtained.

Further, the huge and complicated apparatus to perform feedback during the heat treatment by measuring the deformation amount of the resist pattern in real time is not required.

Although the case in which the baking temperature of the pattern deformation process is changed in each substrate has been described in the embodiment, it is also possible that the baking temperature of the pattern deformation process is changed in each lot which is a unit of the plurality of substrates.

It is possible that parameters such as the baking time and a baking atmosphere (in the air, nitrogen purging, or the like) besides the baking temperature are changed for the baking process condition. Further it is possible that to repeatedly perform the measurement of the monitor pattern and the heat treatment of the pattern deformation in a plurality of times.

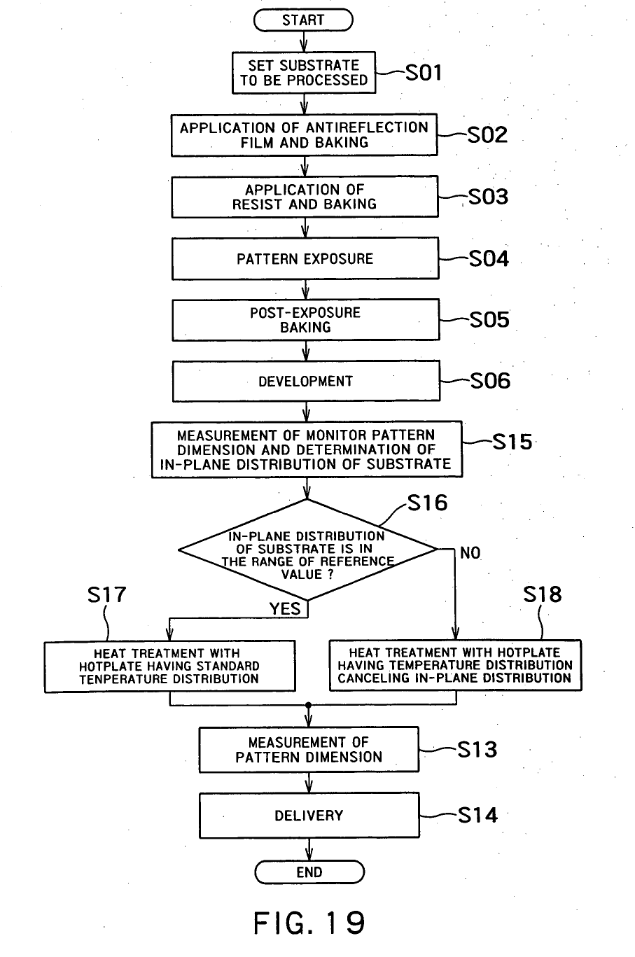

FIG. 19 shows the flow chart of the pattern forming method according to a third embodiment of the invention.

In the third embodiment, the same step as that in the second embodiment is indicated by the same reference sign, and the description is omitted.

As shown in FIG. 19, the third embodiment differs from the second embodiment in that the in-plane distribution of the monitor pattern dimension on the substrate is measured after the development and the heat treatment is performed by using the hotplate which has a temperature distribution such that the in-plane distribution is cancelled.

Therefore, uniformity of the resist pattern dimension on the substrate surface can be improved in such a manner that the in-plane temperature distribution of the hotplate is controlled by the hotplate in which the plurality of heaters are incorporated so that the in-plane distribution of the monitor pattern dimension on the substrate is cancelled.

Similarly to the second embodiment described above, the substrates in which the silicon oxide film having the film thickness of 1 μm, e.g. the 20 substrates are prepared, and the antireflection film and the KrF positive type chemical amplification resist film are formed in order on the substrate. Then, the monitor pattern is formed by sequentially performing the pattern exposure, the baking, and the development process. For example, a line-and-space (hereinafter referred to as L/S) pattern, in which a pitch between lines is constant at 130 nm and a line width is gradually decreased while one set of lines axisymmetrically face the other set of lines across the central line having the largest line width, is arrayed in the monitor pattern.

This monitor pattern is known as a dose meter. When the monitor pattern is irradiated with light, the monitor pattern acts as a diffraction grating, and a zero-order diffraction light beam and high-order diffraction light beams (mainly a first-order diffraction light beam) are generated.

When only the zero-order light beam is extracted by a slit to expose the resist, in the monitor pattern, a rectangular pattern in which the lines are resolved up to the line having a certain line width which is progressively and symmetrically reduced having a central space therein is exposed.

Because the width of the rectangular pattern is proportional to an effective amount of exposure performed by only the zero-order diffraction light beam, the effective amount of exposure can be determined independently of focus.

It is easy to optically measure the pattern width because the pattern width is in the range from several μm to several tens μm.

Accordingly, when the relationship between the effective amount of exposure and the actual resist pattern dimension is previously determined, the measurement of the width of the resolved rectangular pattern can be converted into the resist pattern dimension which has been actually resolved on the resist.

Even if the resist pattern dimension having the dimension in a nanometer (nm) size is not directly measured with SEM, the in-plane distribution of the resist pattern dimension on the substrate can be rapidly determined.

In the embodiment, the effective amounts of exposure of 50 points in plane are measured to all the 20 substrates, and the in-plane distribution of the pattern dimension is determined (Fifteenth Step S15).

Then, it is decided whether the in-plane-distribution of the substrate is in the range of the reference value or not (Sixteenth Step S16). In the case where the in-plane distribution of the substrate is in the range of the reference value, the heat treatment is performed with the hotplate which is set to the standard temperature distribution (Seventeenth Step S17).

In the case where the in-plane distribution of the substrate is out of the range of the reference value, the heat treatment is performed with the hotplate which is set to the temperature distribution canceling the in-plane distribution of the substrate (Eighteenth Step S18).

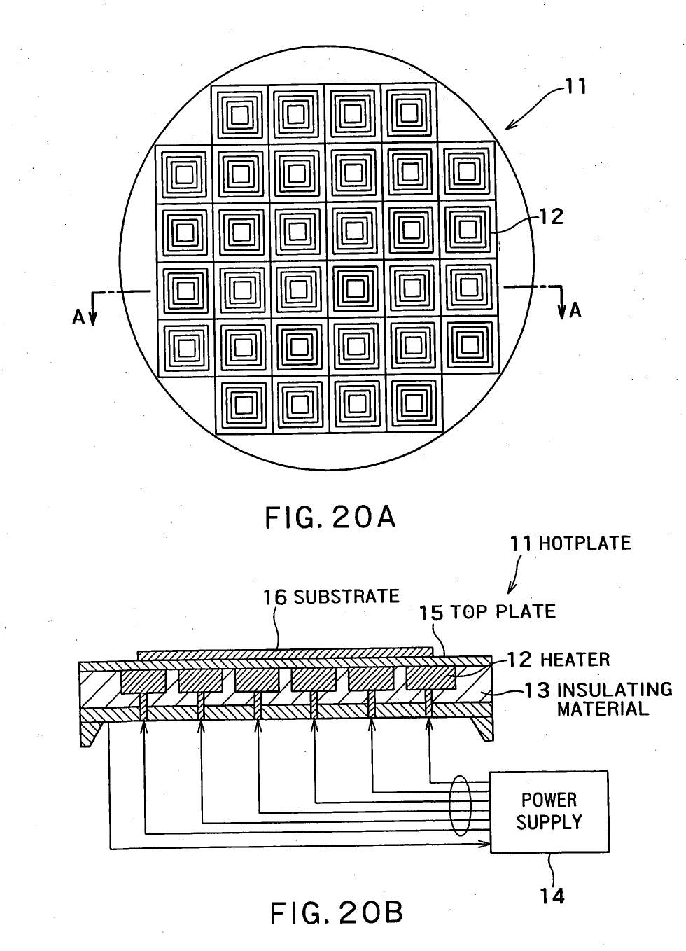

FIGS. 20A and 20B show the hotplate having the temperature distribution canceling the in-plane distribution of the substrate, FIG. 20A is the plan view showing a heater array, and FIG. 20B is the sectional view taken on line A-A of FIG. 20A and viewed in a narrow direction.

As shown in FIGS. 20A and 20B, a plurality of heaters 12, e.g. thirty-six heaters are built in a hotplate 11. Each heater 12 is surrounded with heat insulating material 13 and connected to a power supply 14. Heater temperature can be individually set in each heater 12. A substrate 16 is placed on a top plate 15 with which the heaters 12 are covered, and the heat treatment is performed.

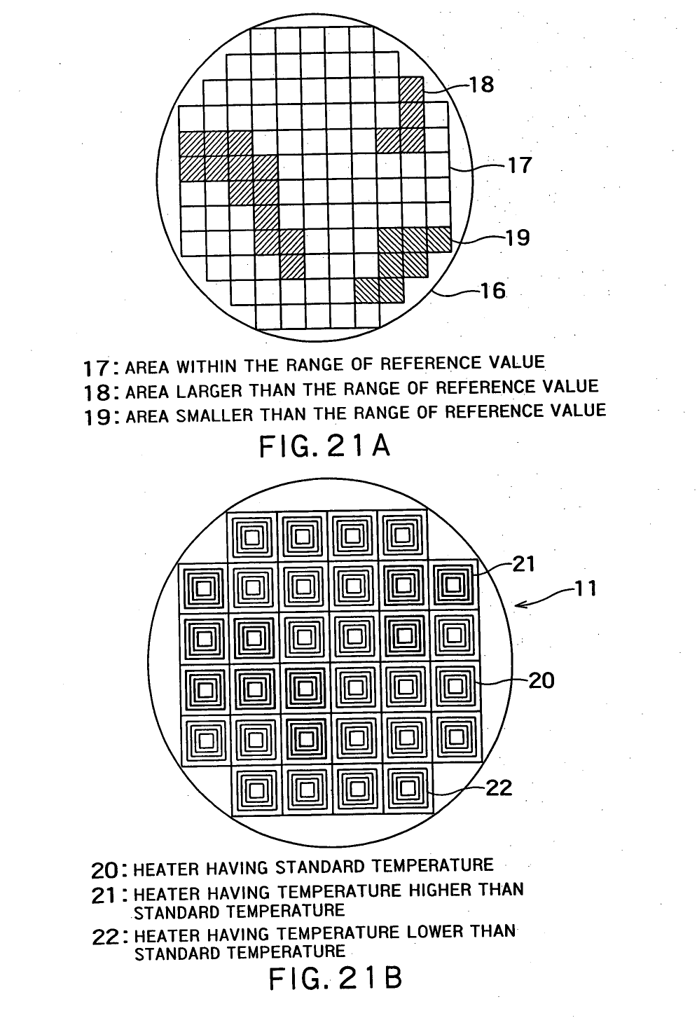

FIGS. 21A and 21B show the heat treatment process in which the resist is deformed with the hotplate 11, FIG. 21A shows the wafer in-plane distribution of the monitor pattern dimension on the substrate after the development, and FIG. 21B shows the temperature distribution of the hotplate 11.

As shown in FIG. 21, in the case where the in-plane distribution of the substrate is present such that an area 17 where the monitor pattern dimension after the development is in the range of the reference value, an area 18 where the monitor pattern dimension after the development is larger than the range of the reference value, and an area 19 where the monitor pattern dimension after the development is smaller than the range of the reference value are present, the in-plane temperature distribution of the hotplate 11 is set so as to cancel the in-plane distribution of the monitor pattern on the substrate.

The temperature of a heater 20 corresponding to the area 17 where the monitor pattern dimension after the development is in the range of the reference value is set to the standard temperature, the temperature of a heater 21 corresponding to the area 18 where the monitor pattern dimension after the development is larger than the range of the reference value is set to the temperature higher than the standard temperature, and the temperature of a heater 22 corresponding to the area 19 where the monitor pattern dimension after the development is smaller than the range of the reference value is set to the temperature lower than the standard temperature respectively.

The in-plane distribution of the monitor pattern dimension on the substrate can be cancelled to uniform the in-plane distribution of the monitor pattern dimension, in such a manner that the substrate 16 is placed on the hotplate 11 having the temperature distribution to perform the heat treatment.

The change in the heating temperature distributing can be also performed by selecting the hotplate which is set to the suitable temperature distribution from the plurality of hotplates which are previously set to the different temperatures.

FIG. 22 shows the measurement results of the monitor pattern dimensions after heat treatment for all the substrates compared with the measurement results of the conventional method, a solid line a in FIG. 22 shows the result performed by the embodiment, and a broken line b shows the result performed by the conventional method. As can be seen from FIG. 22, the experiment shows that the variations in monitor pattern dimension on the substrate are reduced to two-third, compared with the conventional method.

In target values of the monitor pattern dimension after the heat treatment, the line width is 160 nm and the space width is 100 nm (L/S). On the other hand, in the measured average values of the monitor pattern dimension, the line width was 158 nm and the space width was 102 nm (L/S). The measured average values of the monitor pattern dimension were substantially equal to the target values of the monitor pattern dimension after the heat treatment.

As described above, in the pattern forming method according to the third embodiment of the invention, the in-plane distribution on the substrate of the deformation amount of the resist is controlled in each substrate by the adjustment of the in-plane distribution of the heating temperature of the hot plate 11 by adopting a feedforward method so that the in-plane distribution of the resist pattern dimension after the development are cancelled in the resist pattern deformation process, so that the in-plane variations in resist pattern dimension are improved.

Accordingly, the dimension accuracy of the resist pattern can be improved, and the desired pattern in which the variations in resist pattern dimension among the substrates are small can be obtained.

Further, the huge and complicated apparatus to perform feedback during the heat treatment by measuring the deformation amount of the resist pattern in real time is not required.

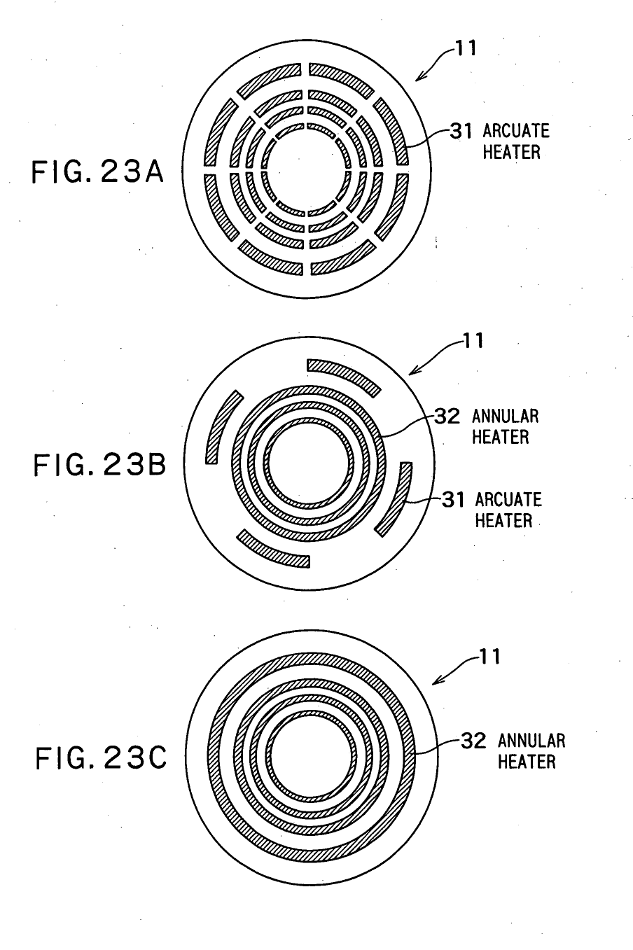

FIGS. 23A to 23C are the plan view showing the hotplate according to the modifications of the third embodiment of the invention. The modifications of the invention differ from the third embodiment in that the heaters are configured to be formed in the shape of an annulus, an arc, or a combination of the annulus and the arc.

In the hotplate 11 of the modification, as shown in FIG. 23A, thirty-two arcuate heaters 31 are arranged in the circular hotplate 11, while the thirty-two arcuate heaters 31 are coaxially and radially divided into four and the thirty-two arcuate heaters 31 are also divided into eight in a circumferential direction.

Each of the arcuate heaters 31 is surrounded with the heat insulating material (not shown) and connect to a power supply (not shown). The heater temperature can be individually set in each of the arcuate heaters 31. The substrate (not shown) is placed on a top plate (not shown) with which the arcuate heaters 31 are covered, and the heat treatment is performed.

In FIG. 23B, three annular heaters 32 are coaxially arranged and the four-divided arcuate heaters 31 are arranged in the circumferential direction in outermost periphery. In FIG. 23C, four annular heaters 32 are coaxially arranged. Each of the arcuate heaters 31 and each of the annular heaters 32 are surrounded with the heat insulating material (not shown) and connected to the power supply (not shown). The heater temperature can be individually set in each of the arcuate heaters 31 and each of the annular heaters 32.

Since the heater is formed in the shape of the annulus, the arc, or the combination of the annulus and the arc, the temperature distribution is easy to adjust. In the case where the in-plane distribution of the resist pattern dimension on the substrate has the coaxial shape, the modifications are particularly effective.

As described above, in the modifications, the in-plane distribution on the substrate of the deformation amount of the resist is controlled in each substrate by the adjustment of the in-plane distribution of the heating temperature of the hotplate by adopting a feed forward method so that the in-plane distribution of the resist pattern dimension after the development are cancelled in the resist pattern deformation process, so that the in-plane variations in resist pattern dimension are improved.

Although the heater has the annular or arcuate shape has been described in the modifications, the invention is not limited to the modifications, and it is possible that the heater has a polygonal shape including rod heaters or a part of the polygonal shape.

Another modification of the third embodiment of the invention utilizes contradictory temperature dependence, in which the higher the baking temperature is increased, the larger the aperture dimension of the resist pattern after the development is finished in the post-exposure baking process and, on the contrary, the higher the heat treatment temperature is increased, the smaller the aperture dimension of the resist pattern is finished in the resist deformation process. The hotplate shown in FIGS. 20A and 20B or FIGS. 23A to 23C, which was used as the hotplate having the temperature distribution canceling the in-plane distribution of the wafer in the post-exposure baking process, is used for the heat treatment of the resist pattern deformation process.

The same hotplate is used for the hotplate of the post-exposure baking process and the hotplate of the resist pattern deformation process by changing only the setting value of the temperature. As a result, it is possible to cancel influence of the in-plane temperature distribution of the hotplate.

As described above, in the another modification, since the post-exposure baking and the resist deformation heat treatment have the reverse temperature dependence to the resist pattern dimension respectively, each fluctuation is automatically cancelled with the same hotplate by utilizing the reverse temperature dependence.

Therefore, while the in-plane uniformity of the resist pattern dimension on the substrate can be improved, the number of hotplates used can be decreased.

Further, since the fine adjustment of the temperature distribution is reduced, there is an advantage that the manufacturing process is simplified.

Although the in-plane uniformity on the substrate after the resist pattern deformation is improved by adjusting the in-plane temperature distribution of the hotplate having the plurality of heaters in the third embodiment, the invention is not limited to the third embodiment. It is possible to perform the heat treatment by combining the plurality of hotplates whose in-plane temperature distributions are different from one another.

In the second and third embodiments, the case in which the resist pattern is formed on an interlayer insulating film of the silicon oxide film formed on the substrate has been described, the invention is not limited to the second and third embodiments, and various changes and modifications of the invention can be applied.

The semiconductor device manufacturing method which uses the pattern forming method according to a fourth embodiment of the invention will be described below referring to the drawings.

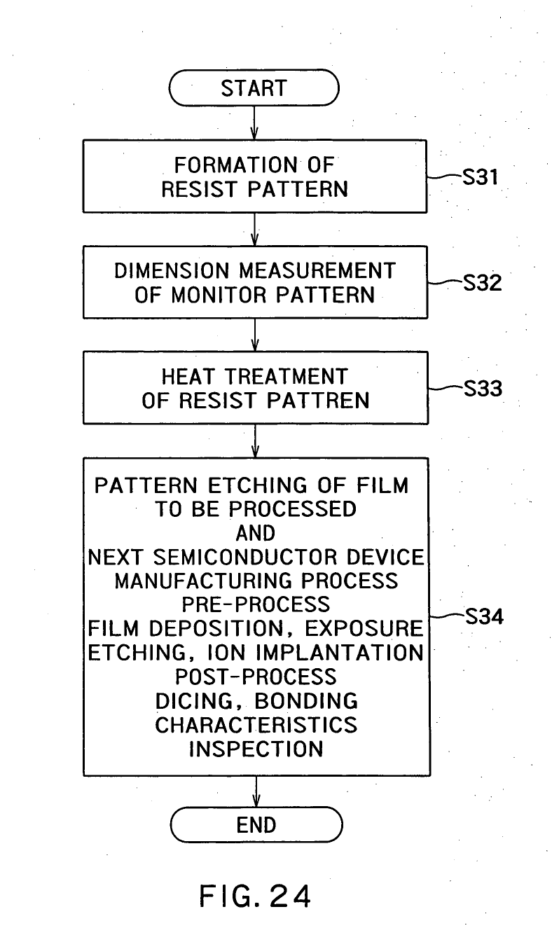

FIG. 24 shows the flow chart of the semiconductor device manufacturing method which adopts the pattern forming method according to the fourth embodiment of the invention.

After the resist film is formed on the substrate according to First Step to Sixth Step shown in FIG. 16, the pattern is exposed to the resist film, and the baking and the development process are performed to form the resist pattern (First Process) (Thirty-first Step S31).

According to Seventh Step shown in FIG. 16, the dimension of the predetermined monitor pattern arranged in the resist pattern is measured to determine the in-plane average value of the substrate (Second Process) (Thirty-second Step S32).

According to the Eighth Step to Fourteenth Step shown in FIG. 16, the in-plane average value of the substrate and the predetermined reference value are compared and the heat treatment condition is controlled to deform the resist pattern so that the resist pattern becomes the desired dimension (Third Process) (Thirty-third Step S33).

The following processes for manufacturing various devices, including the process, in which the film to be processed is etched by using the obtained resist pattern to form the pattern having the desired dimension, are performed (Fourth Process) (Thirty-fourth Step S34).

In Thirty-fourth Step, pre-processes for manufacturing various devices are further performed. For example, a film deposition, exposure, etching, ion implantation, and the like which are required to form a gate area, a source area, a drain area, and an electrode are performed in the manufacture of an insulated gate field effect transistor.

It is possible to include the process which repeats the resist pattern forming process from Thirty-first Step to Thirty-third Step.

Finally, in the post-process for the device manufacturing, dicing of the substrate on which the semiconductor tips are formed is performed to divide the substrate into the semiconductor tips, mount-bonding is performed to lead frames, and the semiconductor tips is molded with a resin to finish the semiconductor device.

As described above, the semiconductor device manufacturing method according to the fourth embodiment of the invention which adopts the pattern forming method according to the second embodiment of the invention can obtain the semiconductor device, in which variations in electrical characteristics caused by the variations in resist pattern dimension among the substrates are small and the electrical characteristics are stable.

It is also possible to manufacture the semiconductor device by adopting the pattern forming method according to the third embodiment of the invention. In this case, the semiconductor device in which the variations in electrical characteristics caused by the variations in resist pattern dimension in the plane of the substrate are small and the electrical characteristics are stable is obtained.

As described above, according to the pattern forming method of the invention, the desired pattern dimension can be finally obtained in the plane of the substrate to be processed or among the substrates to be processed. That is to say, according to the invention, the desired pattern in which the variations in resist pattern dimension are small in the plane of the substrate to be processed or among the substrates to be processed can be obtained.

Therefore, according to the semiconductor device manufacturing method of the invention which adopts the present pattern forming method, the stable electrical characteristics can be obtained.

1. A baking apparatus comprising:
a hotplate which performs heat treatment to a substrate placed on said hotplate;
a base which has at least three support pins passing through through-holes made in said hotplate and supporting the substrate on said hotplate from a backside of the substrate, said base being vertically movably placed; and
a plurality of sensors which are provided at a tip portion of said each support pin respectively, said plurality of sensors sensing contact with the substrate.

2. A baking apparatus according to claim 1, wherein each of said plurality of sensors independently senses the contact with the substrate.

3. A baking apparatus according to claim 1, wherein said each sensor is a piezoelectric element.

4. A baking apparatus according to claim 1, wherein said each sensor is a capacitance type element.

5. A baking apparatus according to claim 1, wherein it is decided that failure treatment is sensed, when measured time difference of contact timing with the substrate in said each sensor in supporting the substrate by said support pins after heat treatment exceeds an allowance which is previously arbitrarily set to said time difference.

6. A baking apparatus according to claim 5, further comprising a warning device which issues a visual warning or an audio warning when the failure treatment is sensed.

7. A baking apparatus according to claim 5, wherein operation is interrupted when the failure treatment is sensed.

8. A baking apparatus according to claim 5, wherein the substrate which is of a subject of processing is rejected from a manufacturing process when the failure treatment is sensed.

9. A baking apparatus according to claim 5, wherein the time difference of the contact timing with the substrate in said each sensor in moving the substrate on said support pins is measured before the heat treatment, and the time difference is used as a correction value for the time difference which is measured after the heat treatment.

10. A baking apparatus according to claim 1, wherein lifting speed can be adjusted in said base.

11. A baking apparatus according to claim 1, further comprising a guide member in which an upper surface of the guide member is formed in a shape of an inclined surface whose central portion side of said hotplate is lower than an outer peripheral side, said guide member being provided in a part of or the whole of a periphery of said hotplate.

12. A substrate heat treatment method including performance of heat treatment to a substrate by using a baking apparatus comprising:
a hotplate which performs heat treatment to a substrate placed on said hotplate;
a base which has at least three support pins passing through through-holes made in said hotplate and supporting the substrate on said hotplate from a backside of the substrate, said base being vertically movably placed; and
a plurality of sensors which are provided at a tip portion of said each support pin respectively, said plurality of sensors sensing contact with the substrate.

13. A semiconductor device manufacturing method including performance of heat treatment to a substrate by using a baking apparatus comprising:
a hotplate which performs heat treatment to a substrate placed on said hotplate;
a base which has at least three support pins passing through through-holes made in said hotplate and supporting the substrate on said hotplate from a backside of the substrate, said base being vertically movably placed; and
a plurality of sensors which are provided at a tip portion of said each support pin respectively, said plurality of sensors sensing contact with the substrate.

14-33. (canceled)
